(19) United States
(12) Patent Application Publication
(10) Pub. No.: US 2014/0197394 A1
(43) Pub. Date: Jul. 17, 2014

(54) ORGANIC LIGHT EMITTING DEVICE AND MANUFACTURING METHOD THEREFOR

(71) Applicant: CANON KABUSHIKI KAISHA, Tokyo (JP)

(72) Inventors: Manabu Otsuka, Kawasaki-shi (JP); Satoru Shiobara, Funabashi-shi (JP)

(73) Assignee: CANON KABUSHIKI KAISHA, Tokyo (JP)

(21) Appl. No.: 14/151,736

(22) Filed: Jan. 9, 2014

(30) Foreign Application Priority Data
Jan. 11, 2013 (JP) 2013-004003

(51) Int. Cl. H01L 51/50

(52) U.S. Cl. CPC H01L 51/5088
USPC 257/40; 438/46

(57) ABSTRACT

Provided is an organic light-emitting device including a display region provided with an organic light-emitting device provided on a substrate, where the organic light-emitting device includes: a first electrode provided on the substrate; a hole injection layer provided on the first electrode; an organic compound layer including a light-emitting layer, which is provided on the hole injection layer; and a second electrode provided on the organic compound layer, the hole injection layer is a layer including an organic compound having an electron-withdrawing substituent, and the organic compound layer coats an end of the hole injection layer, which is provided outside the display region.

### BACKGROUND OF THE INVENTION

### Field of the Invention

Organic light-emitting devices refer to devices which each have a plurality of organic light-emitting devices arranged on a base material in a matrix form. In this case, multi-color display becomes possible when organic light-emitting devices for emitting light in any color of different colors from each other, for example, red, green, and blue are arranged in combination with one by one for each color so as to form a set of pixels.

The organic light-emitting devices constituting the organic light-emitting devices each have a pair of electrodes and an organic light-emitting layer placed between the pair of electrodes. The emission colors of the organic light-emitting devices can be changed by appropriately selecting luminescent materials contained in the light-emitting layers.

In order to increase the luminous efficiency of the organic light-emitting device, it is known that a hole injection layer, a hole transport layer, an electron injection layer, an electron transport layer, and the like for increasing carrier injecting properties are provided between the electrodes and the organic light-emitting layer. Japanese Patent No. 4537207 discloses an organic material having an electron-withdrawing substituent, which is preferred as a hole injection layer.

Now, vapor deposition methods through metal masks are widely known as a method for forming the organic compound layers. However, the vapor deposition methods through metal masks are low in deposition accuracy due to low accuracy in alignment between the metal mask and a film formation substrate, thermal expansion of the metal mask, etc., and unsuitable for the fabrication of high-definition display devices.

In order to solve the problem, Japanese Patent No. 4507759 discloses a method for selectively forming an organic compound layer with a high degree of accuracy by the use of a photolithography method, without using any high-definition metal mask. Specifically, an intermediate layer composed of a water-soluble polymer and a resist layer are sequentially provided on an organic compound layer formed over the entire substrate, and the resist layer and the intermediate layer are subjected to patterning into a desired shape by a known approach. Then, with the resist layer and intermediate layer as a mask, the organic compound layer is subjected to patterning. Then, after the patterning of the organic compound layer, the intermediate layer is dissolved by water to remove (lift-off) the intermediate layer and the resist layer on the organic compound layer. In accordance with the series of steps, an organic compound layer can be obtained which has a desired pattern shape.

### SUMMARY OF THE INVENTION

An organic light-emitting device according to the present invention includes a display region with an organic light-emitting device placed on a substrate, and characteristically, the organic light-emitting device includes: a first electrode provided on the substrate; a hole injection layer provided on the first electrode; an organic compound layer including a light-emitting layer, which is provided on the hole injection layer; and a second electrode provided on the organic compound layer, the hole injection layer is a layer including an organic compound having an electron-withdrawing substituent, and a layer included in the organic compound layer coats an end of the hole injection layer, which is provided outside the display region.

Further features of the present invention will become apparent from the following description of exemplary embodiments (with reference to the attached drawings).

### BRIEF DESCRIPTION OF THE DRAWINGS

FIGS. 1A to 1C are frame formats illustrating an example according to an embodiment in an organic light-emitting device A according to the present invention, where FIG. 1A is a plan view, FIG. 1B is a cross-sectional view illustrating a cross section along the line XX′ in FIG. 1A, and FIG. 1C is a cross-sectional view of a cross section along the line Y in FIG. 1B.

FIGS. 2A to 2C are frame formats illustrating an example according to an embodiment in an organic light-emitting device B according to the present invention, where FIG. 2A is a plan view, FIG. 2B is a cross-sectional view illustrating a cross section along the line AA′ in FIG. 2A, and FIG. 2C is a cross-sectional view illustrating a modification example of FIG. 2B.

FIGS. 3A to 3E are schematic cross-sectional views illustrating a first embodiment in a method for manufacturing an organic light-emitting device according to the present invention.

FIGS. 4A to 4I are schematic cross-sectional views illustrating a second embodiment in a method for manufacturing an organic light-emitting device according to the present invention.

FIGS. 5A to 5C are schematic plan views illustrating examples of deposition regions for each layer.

FIGS. 6A to 6K are schematic cross-sectional views illustrating a third embodiment in a method for manufacturing an organic light-emitting device according to the present invention.

FIGS. 6L to 6P are schematic cross-sectional views illustrating the third embodiment in a method for manufacturing an organic light-emitting device according to the present invention.

FIGS. 7A and 7B are frame formats illustrating an organic light-emitting device prepared in Example 2, where FIG. 7A is a plan view, and FIG. 7B is a diagram view illustrating a cross section along the line BB′ in FIG. 7A.

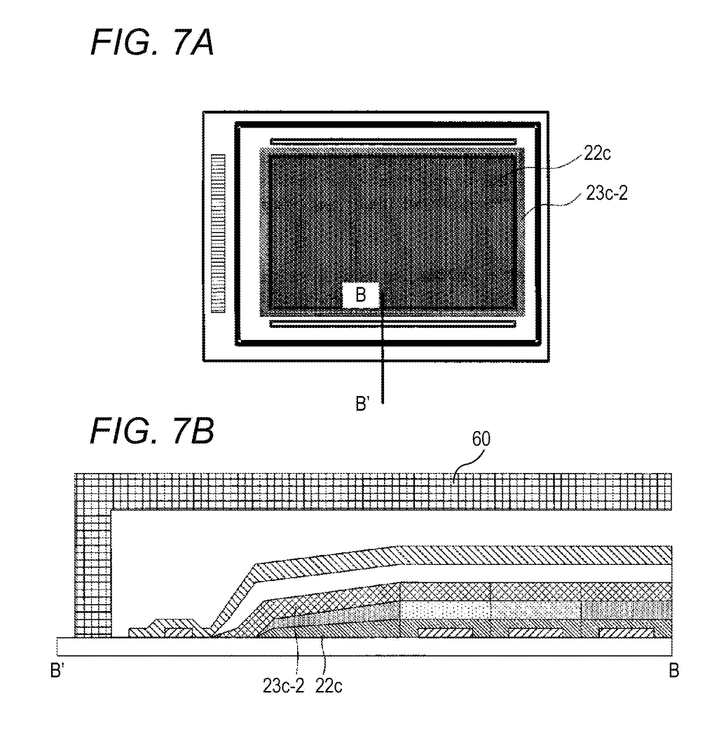

### DESCRIPTION OF THE EMBODIMENTS

In the method disclosed in Japanese Patent No. 4507759, for the purpose of reducing damage to the organic compound layer when the resist layer is applied, exposed, developed, or the like, a stacked body of the intermediate layer and photoresist layer stacked from the organic compound layer side is used as a mask. Further, a water-soluble material is used as the constituent material of the intermediate layer. Thus, the organic compound layer is not supposed to be damaged, because the intermediate layer can be dissolved in water or alcohol to remove the photoresist layer.

On the other hand, the organic compound layer formed in a desired shape in the method disclosed in Japanese Patent No. 4507759 may include a hole injection layer which is also a layer in contact with an electrode (anode) in some cases. In this case, when an organic compound having an electron-withdrawing substituent is used for the hole injection layer, the ends of the hole injection layer may be cracked or peeled in some cases in the steps of bringing the intermediate layer into contact with a polar solvent such as water or alcohol to dissolve and thereby remove the intermediate layer, or the step of cleaning the surface. In that case, fragments of the cracked or peeled layer may fly into the display region to cause defective light emissions in some cases.

In addition, when a residue of the intermediate layer material or the resist material remains on the organic compound layer constituting the organic light-emitting device, the device characteristics may be degraded in some cases. Methods for removing such a residue include a method of forming in advance a sacrifice layer that is soluble in polar solvents between the intermediate layer and the organic compound layer. When the sacrifice layer is dissolved in a polar solvent after removing the intermediate layer, it becomes possible to remove a residue of the intermediate layer along with the sacrifice layer.

However, when an organic material having an electron-withdrawing substituent is used as the constituent material of the hole injection layer as in Japanese Patent No. 4537207, the ends of the hole injection layer may be cracked or peeled in some cases in the step of removing the sacrifice layer. Alternatively, fragments of the hole injection layer may fly into the display region to cause defective light emissions in some cases.

In addition, when the organic light-emitting device is subjected to sealing with a highly dampproof inorganic film such as silicon nitride and aluminum oxide, without using any photolithography method for the patterning of the organic compound layer, it is conceivable as a measure to remove foreign substances on the organic compound layer by cleaning the surface of the organic compound layer with an organic solvent. Also in this case, there is a possibility that the ends of the hole injection layer may cracked or peeled.

The present invention has been achieved in order to solve the problems mentioned above, and provides an organic light-emitting device which has favorable light emitting properties, and has no cracked or peeled layer in contact with an electrode, such as a hole injection layer, and a method for manufacturing the organic light-emitting device.

The present invention will be described below.

### [Organic Light-Emitting Device]

An organic light-emitting device according to the present invention has at least one organic light-emitting device provided on a substrate. When the organic light-emitting device herein has two or more organic light-emitting devices, the emission colors for each organic light-emitting device may be the same color or different colors. In addition, when the organic light-emitting device has two or more organic light-emitting devices, the forms for the arrangement of the respective organic light-emitting devices include, for example, the form in which pixels composed of multiple organic light-emitting devices in combination are arranged in a matrix, but the present invention is not limited to this form.

In the present invention, the organic light-emitting device constituting the organic light-emitting device has a first electrode, a hole injection layer, an organic compound layer, and a second electrode. The first electrode herein is an electrode provided on a substrate, and is a member also referred to as a lower electrode. The hole injection layer is a layer provided on the first electrode. The organic compound layer is a layer including a light-emitting layer, which is provided on the hole injection layer. Specifically, a hole transporting layer, an electron blocking layer, a hole blocking layer, an electron transporting layer, etc. are included in addition to the light-emitting layer. The second electrode is an electrode provided on the organic compound layer, and a member also referred to as an upper electrode.

In the present invention, the hole injection layer is a layer including an organic compound having an electron-withdrawing substituent. In addition, in the present invention, at least one layer included in the organic compound layer has a function as a layer for covering ends of the hole injection layer, that is, protecting the hole injection layer.

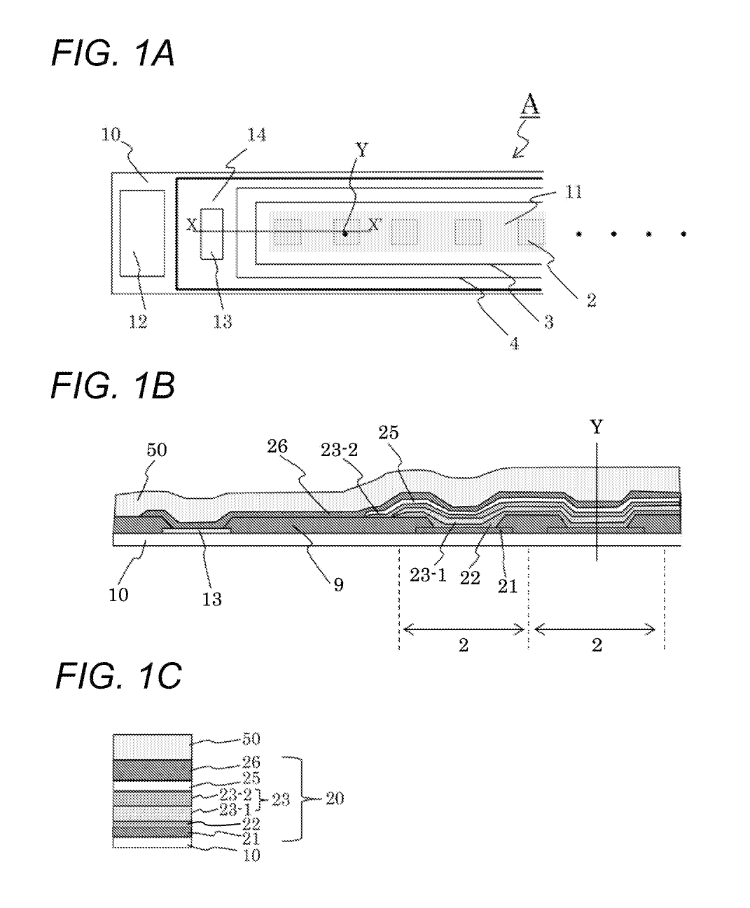

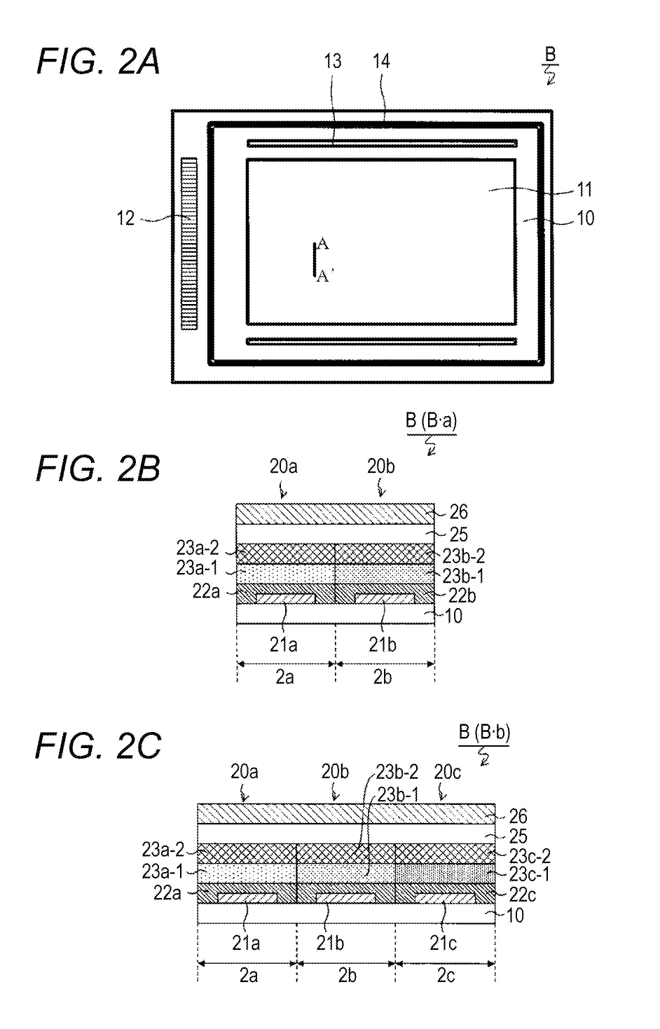

The organic light-emitting device will be described below with reference to the drawings, and furthermore, each step in embodiments of the present invention will be specifically described with reference to the drawings. It is to be noted that common or corresponding members in FIGS. 1A through 2C are denoted by the same signs. In addition, well known or known technique in the art can be applied to sections which are not particularly illustrated or described in this specification. In addition, the present invention is not to be considered limited to the embodiments described below by way of example, except for the respects related to the present invention.

FIGS. 1A to 1C are frame formats illustrating an example according to an embodiment in an organic light-emitting device according to the present invention, where FIG. 1A is a plan view, FIG. 1B is a cross-sectional view illustrating a cross section along the line XX′ in FIG. 1A, and FIG. 1C is a view of a cross section along the line Y in FIG. 1B. In addition, FIGS. 2A to 2C are frame formats illustrating an example according to an embodiment in an organic light-emitting device according to the present invention, where FIG. 2A is a plan view, FIG. 2B is a cross-sectional view illustrating a cross section along the line AA′ in FIG. 2A, and FIG. 2C is a cross-sectional view illustrating a modification example of FIG. 2B.

The organic light-emitting devices A and B respectively illustrated in FIGS. 1A and 2A are each provided with a substrate 10, a display region 11, an external connection terminal 12, a cathode contact 13, and a sealing region 14.

Although not illustrated FIG. 1A or 2A, the substrate 10 is provided with a circuit electrically connected to any of the external connection terminal 12, the cathode contact 13, and electrodes (first electrodes) provided in the display region 11. The external connection terminal 12 is a terminal for supplying external signals or power-supply voltages to the circuit, not illustrated.

The cathode contact 13 is a contact part provided on the substrate 10 for connecting a second electrode 26 (cathode) and the circuit electrically connected to the external connection terminal 12. Further, the cathode contact 13 is provided at an outer edge of the display region 11 within the sealing region 14, as illustrated in FIGS. 1A and 2A.

The sealing region 14 refers to a region cut off from the outside air by a sealing member. In the case of using a glass material as the sealing member, a region (not illustrated) for contact between the substrate 10 and the glass material is provided around the sealing region 14 with an adhesive, frit, or the like interposed therebetween. Alternatively, in the case of using an inorganic film as the sealing member, a region for contact between an end of the inorganic material thin film and the substrate 10 or a film of inorganic material provided on the substrate 10 is provided around the sealing region 14. Highly dampproof inorganic materials such as silicon nitride, silicon oxide, and aluminum oxide can be used as the thin film used for the sealing member. It is to be noted that the display region 11 and the cathode contact 13 are provided within the sealing region 14 as illustrated in FIGS. 1A and 2A.

The display region 11 refers to a region that has a plurality of pixels arranged on the substrate 10. In the organic light-emitting device A, each of the pixels has the same cross-section structure as illustrated in FIG. 1C. In the organic light-emitting device B, each of the pixels includes at least two types of sub pixels: a first sub pixel 2a and a second sub pixel 2b as illustrated in FIG. 2B. For example, as illustrated in FIG. 2C, three types of sub pixels (first sub pixel 2a, second sub pixel 2b, and third sub pixel 2c) may be included, or four or more types of sub pixels may be included.

The pixels in FIGS. 1A to 1C and the respective sub pixels in FIG. 2A to 2C are each provided with at least one organic light-emitting device 20. The organic light-emitting device 20 has a first electrode 21 provided on the substrate 20, a hole injection layer 22, an organic compound layer 23, an electron injection layer 25, and a second electrode 26. In FIGS. 2B and 2C, distinctions are made by adding symbols a, b, and c respectively to the signs of: layers included in a first organic light-emitting device 20a provided in the first sub pixel 2a; layers included in a second organic light-emitting device 20b provided in the second sub pixel 2b; and layers included in a third organic light-emitting device 20c provided in the third sub pixel 2c. Hereinafter, in the case of explaining general matters common in each pixel, the sings will be used without adding the symbol a, b, or c.

In the organic light-emitting device illustrated in FIGS. 2A to 2C, only one pixel composed of different types of sub pixels in combination one by one is illustrated for simplification of the drawings. However, in fact, the display region 11 has a plurality of pixels two-dimensionally arranged therein.

Now, main constituent members of the organic light-emitting device according to the present invention will be described.

The hole injection layer 22 of each organic light-emitting device 20 includes an organic compound having an electron-withdrawing substituent.

The hole injection layer 22 is provided in contact with the first electrode 21, and a layer for making a contribution to lowering the voltage to the organic light-emitting device 20. In particular, when the hole injection layer 22 includes an organic compound having an electron-withdrawing substituent, the organic compound functions as an acceptor. More specifically, the organic compound having an electron-withdrawing substituent produces the effect of increasing the hole density in the hole injection layer 22, or increasing the hole mobility. The provision of the hole injection layer 22 can lower the driving voltage of the organic light-emitting device 20, and improve the carrier balance, thereby allowing the lifetime of the organic light-emitting device 20 to be made longer.

The organic compound having an electron-withdrawing substituent functions as an acceptor in the hole injection layer, because the electron-withdrawing substituent cause polarization by attracting electrons in the molecules to the electron-withdrawing substituent, thereby decreasing the electron density at the site substituted with the substituent, and increasing the electron acceptability as molecules. Examples of the electron-withdrawing substituent include, for example, halogen (—F, —Cl, —Br, —I), a cyano group (—CN), a nitro group (—NO2), a carbonyl group (—CO—), and a sulfone group (—SO3H).

Examples of the organic compound having an electron-withdrawing substituent, which can be included in the hole injection layer 22, include the following compounds, for example.

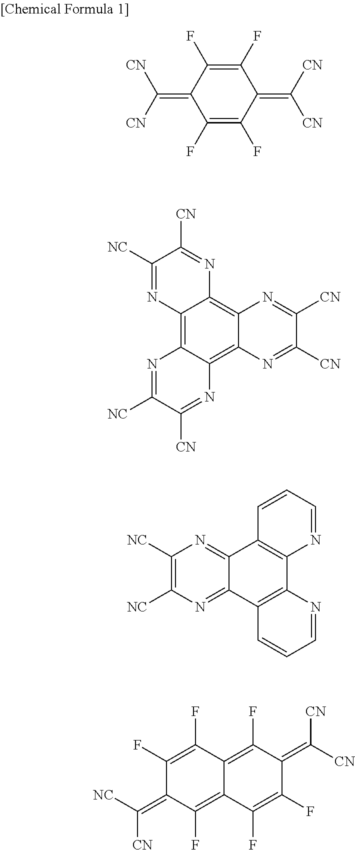

When the organic compound having an electron-withdrawing substituent is included in the hole injection layer 22 as described above, polarization is caused in the molecules of the organic compound. For this reason, the organic compound undergoes an increase in affinity with polar solvents. On the other hand, in the manufacture of the organic light-emitting device illustrated in FIGS. 1A to 1C or FIGS. 2A to 2C, the hole injection layer 22 including the organic compound and an organic compound layer 23-1 are sequentially stacked on the substrate 10. Therefore, when the manufacturing method with the use of the photolithography process as disclosed in Japanese Patent No. 4507759 is applied to the manufacture of such a display device, the polar solvent for use in the process may penetrate into the interface between the hole injection layer 22 and the substrate 10 in some cases. This penetration of the polar solvent is significant at ends of the hole injection layer 22.

When the polar solvent penetrates into the interface between the hole injection layer 22 and the substrate 10, the adhesion is decreased between the hole injection layer 22 and the substrate 10. As a result, the hole injection layer 22 and the layer formed on the hole injection layer may cause peeling, and accordingly cracking in some cases. In addition, when the constituent material of the hole injection layer has high solubility in the polar solvent used, the hole injection layer 22 is at least partially etched, and the hole injection layer 22 causes peeling or cracking.

The problem described above can be caused, not only when the hole injection layer 22 is a layer composed of only the organic compound having an electron-withdrawing substituent, but also even when the hole injection layer is formed from a layer composed of the organic compound having an electron-withdrawing substituent and other hole transport material.

On the other hand, the hole injection layer 22 including the organic compound having an electron-withdrawing substituent has extremely high adhesion to the first electrode 21. For this reason, in the display region 11, the hole injection layer 22 is less likely to cause cracking or peeling as described above. This is believed to be because the electron-withdrawing group increases the intermolecular interaction between the organic compound and the constituent material of the first electrode 21 to increase the adhesion, which is also support for the enhancement of charge injection properties.

Therefore, in the case of providing the hole injection layer 22 including the organic compound having an electron-withdrawing substituent as a layer constituting the organic light-emitting device, damage due to the polar solvent or the like may be reduced as much as possible at a peripheral edge of the display region 11. In particular, there is a need to keep the hole injection layer 22 from being damaged by the polar solvent for use in the process for manufacturing the organic light-emitting device.

In the present invention, in order to solve the problem, prior to processes with the use of polar solvents, specifically steps such as cleaning, lift-off, and etching, the ends of the hole injection layer 22 are covered in advance with at least one layer 23-2, for example hole blocking layer, included in the organic compound layer 23.

In the present invention, a material that is low in etching rate against polar solvents for use in the manufacture of the organic light-emitting device is selected for the constituent material of the organic compound layer 23-2 for covering the ends of the hole injection layer 22. The etching rate against the polar solvents, which is required for the organic compound layer 23-2, will be described in detail later. It is to be noted that the organic compound layers 23-1 and 23-2 may be simply referred to collectively as the organic compound layer 23 in some cases.

Examples of the material herein which is low in etching rate against the polar solvents include organic compounds composed of carbon rings. Specifically, linked compounds composed of a plurality of carbon ring compounds such as naphthalene, fluorene, fluoranthene, chrysene, anthracene, tetracene, phenanthrene, pyrene, and triphenylene, are preferred, for example, the organic compound materials listed below.

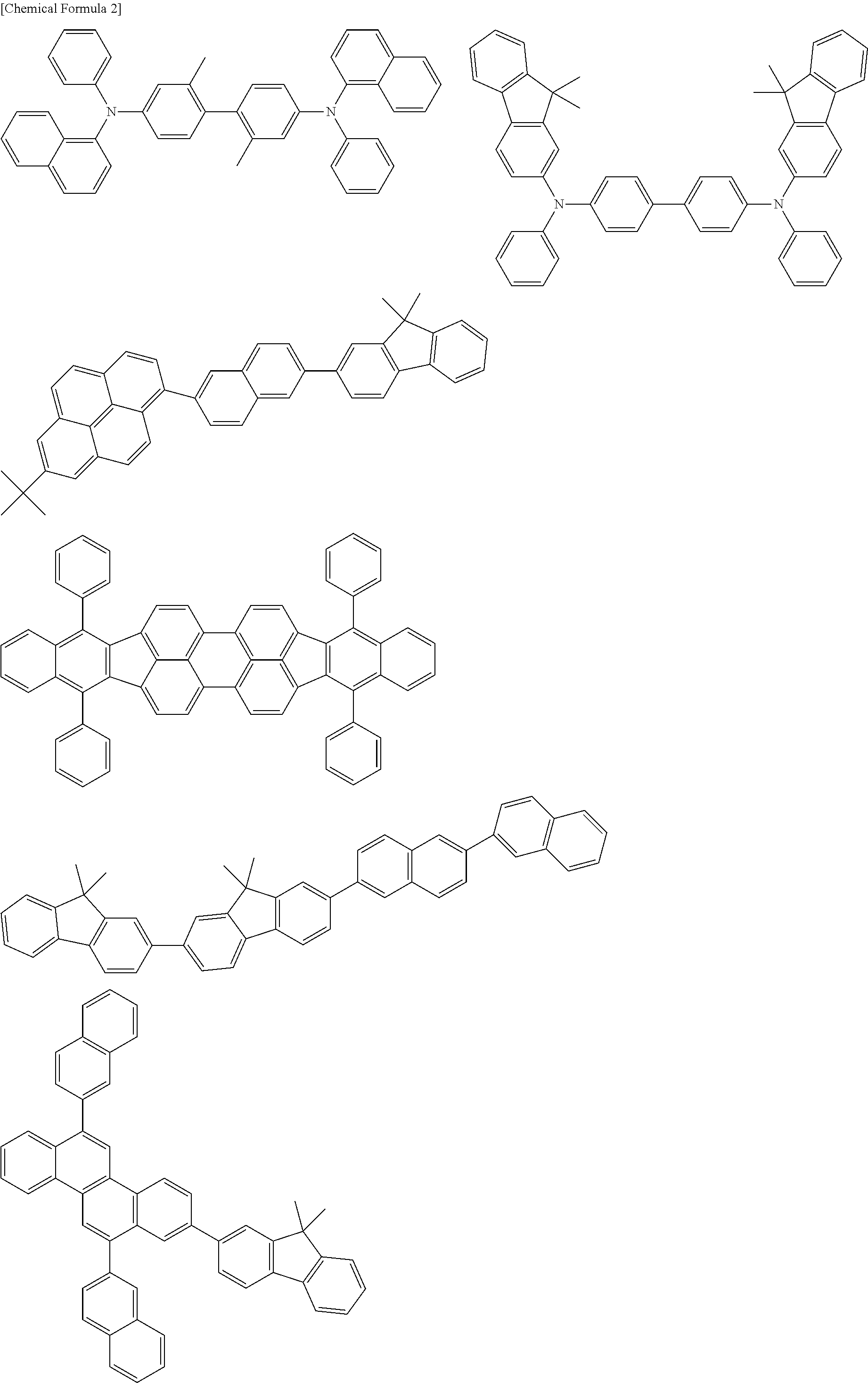

Next, a method for manufacturing the light-emitting device will be discussed. In the manufacturing method according to the present invention, the substrate 10 with layers formed up to the organic compound layer is brought into contact with water in a cleaning step in the case of the organic light-emitting device A, or brought into contact with water in a lift-off step, and with a polar solvent in a peeling layer etching step in the case of the organic light-emitting device B. Therefore, in this regard, it is important for the ends of the hole injection layer including the organic compound having at least an electron-withdrawing substituent to be covered with at least one layer included in the organic compound layer.

### First Embodiment

### Method for Manufacturing Organic Light-Emitting Device A

A method for manufacturing the organic light-emitting device A illustrated in FIG. 1 will be described as an example of a method for manufacturing an organic light-emitting device according to the present invention. The organic light-emitting device A is specifically, a printer head. The method for manufacturing the organic light-emitting device A includes at least the following steps (A) to (D) below.

### (A) Step of Forming Hole Injection Layer (Hole Injection Layer Formation Layer)

(B) Step of Forming Organic Compound Layer including Light-Emitting Layer (Organic Compound Layer Formation Step)
(C) Step of Cleaning Substrate 10 with Polar Solvent (Cleaning Step)

In the present invention, the step (C) (cleaning step) is a step of cleaning foreign substances on the substrate with the use of a polar solvent.

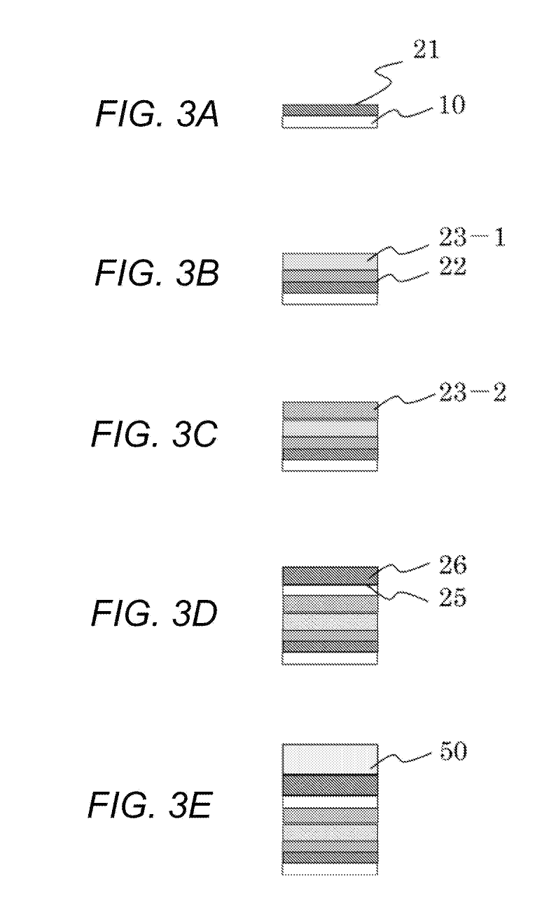

FIGS. 3A to 3E are schematic cross-sectional views illustrating layered structures according to a first embodiment in a method for manufacturing an organic light-emitting device according to the present invention. The method for manufacturing an organic light-emitting device according to the present invention includes the steps (1) to (7) described below.

However, in the present invention, the method for manufacturing an organic light-emitting device is not to be considered limited to the steps (1) to (7) below. Depending on the configuration of the organic light-emitting device to be manufactured, and the materials for use in the manufacturing process, the steps can be deleted, and appropriate changes can be made to the steps.

### (1) Step of Forming First Electrode (FIG. 3A)

First, the first electrode 21 is formed on the substrate 10 (FIG. 3A). As the substrate 10, any substrate can be used without particular limitation, as long as the organic light-emitting device can be manufactured stably, and driven. For example, a substrate with a circuit can be used, which includes: an insulating or semiconducting support substrate such as glass and Si wafers; a driving circuit provided on the support substrate for driving the organic light-emitting device; and a planarizing layer for planarizing unevenness created by providing the driving circuit. In addition, this substrate with a circuit may be further provided with, on the planarizing layer, a separating layer for separating the first electrodes 21 from each other and partitioning the light-emitting region for each sub pixel.

For example, a metal material such as aluminum and silver, a transparent electrode material such as an indium tin oxide (ITO) and an indium zinc oxide, or the like can be used as the specific constituent material of the first electrode 21. It is to be noted that the first electrode 21 can be formed as a single layer composed of the metal material or transparent electrode material in the formation of the first electrode 21, but may be formed as a lamination electrode film obtained by laminating the metal material and the transparent electrode material.

Conventionally known methods such as a vacuum deposition method, a sputtering method, and a CVD method can be used as the method for forming the first electrode 21. Specifically, a conductive layer is formed over the entire surface of the substrate 10 by a vacuum deposition method or the like, and then subjected to patterning for each device by the use of a photolithography method to form first electrodes 21 each corresponding to each organic light-emitting device 20.

In addition, in the case of providing a pixel separating layer 9 for separating the respective first electrodes 21 from each other, an insulating material such as, for example, a polyimide resin, or a silicon nitride or a silicon oxide is deposited over the entire surface of the substrate 10 on the substrate 10 and the first electrodes 21. Then, the layer of the insulating material is subjected to patterning so as to have openings on the first electrodes 21, thereby forming banks.

### (2) Step of Forming Hole Injection Layer and Organic Compound Layer (FIGS. 3B and 3C)

Next, the hole injection layer 22 and the organic compound layer 23 (23-1, 23-2) are sequentially formed on the substrate 10 with the first electrodes 21 formed (FIGS. 3B and 3C). It is to be noted that the hole injection layer 22 and the organic compound layer 23 are layers each constituting the organic light-emitting device 20 included in the sub pixel 2.

As the hole injection layer 22, a layer including an organic compound having an electron-withdrawing substituent is formed as described above. The organic compound layer 23 includes at least a light-emitting layer, and may include layers such as a hole transport layer, an electron blocking layer, a hole blocking layer, and an electron transport layer, in addition to the light-emitting layer.

The constituent material of the organic compound layer 23 can be appropriately selected from among known low-molecular-weight materials or high-molecular-weight materials.

It is to be noted that the organic compound layer also functions as a layer for protecting the hole injection layer 22 as described above. Therefore, there is a need to define in advance the deposition region of the organic compound layer 23 which has the function of protecting the hole injection layer 22, so as to encompass the deposition region of the hole injection layer 22. While FIGS. 1A to 1C illustrate the organic compound layer 23 entirely configured to protect the hole injection layer 22, at least one layer (23-2) included in the organic compound layer 23 may protect the hole injection layer 22.

In the case of forming the organic compound layer 23 or the hole injection layer 22 by a vapor deposition method, the deposition region for each layer can be defined by determining the opening size of a mask, floating the mask with respect to the substrate to increase the component coming around, adjusting the incident angle to the substrate for the deposition, etc. However, the definition of the deposition region is not to be considered limited thereto. In the case of adopting herein the method of adjusting the incident angle to the substrate for the deposition, the incident angle may be set to be small in the formation of the hole injection layer 22, whereas the incident angle may be increased in the formation of a layer (23-2) for covering the ends of the hole injection layer 22.

FIG. 1A illustrates a deposition region 3 for the hole injection layer 22 and a deposition region 4 for the organic compound layer 23-2 for covering the ends of the hole injection layer 22. Because it is only necessary to form the hole injection layer 22 at least in the display region 11, it is only necessary for the deposition region 3 to encompass the display region 11. Because at least one layer included in the organic compound layer 23-2 needs to coat ends of a film to serve as the hole injection layer 22, the deposition region 4 is adapted to encompass the deposition region 3 illustrated in FIG. 1A, and made larger than the deposition region 3.

### (3) Cleaning Step

Next, for the purpose of reducing foreign substances on the substrate, the organic compound layer is cleaned with a polar solvent. In order to keep the organic compound layer 23-2 from being damaged by dissolution, water or an aqueous solution with a high concentration of water is preferably use as a cleaning solvent that is a polar solvent. Examples of the cleaning method include cleaning with a two-fluid nozzle or ultrasonic water. When these methods are applied onto the organic compound layer, the deposition region 3 of the hole injection layer 22 and the deposition region 4 of the organic compound layer 23-2 have the relationship illustrated in FIG. 1A, and thus can prevent the hole injection layer 22 from being damaged or having defect generation.

### (4) Step of Forming Second Electrode, Etc. (FIG. 3D)

Next, the sequential formation of the electron injection layer 25 and the second electrode 26 on the organic compound layer 23-2 completes an organic light-emitting device 1 in FIG. 1C (FIG. 3E). The electron injection layer 25 is a member provided if necessary, and it is not always necessary to provide the electron injection layer 25. In addition, the electron injection layer is formed after the cleaning step, because in general, a water-soluble material containing an alkali metal or an alkali earth metal is preferably used for the electron injection layer. However, in the case of using a water-resistant electron injection layer 25, the electron injection layer 25 may be formed before the cleaning step.

Known electrode materials such as metal materials, e.g., Al and Ag, and transparent electrode materials, e.g., an indium tin oxide (ITO) and an indium zinc oxide can be used as the constituent material of the second electrode 26. In addition, a lamination electrode film composed of a layer of metal material and a transparent electrode material can be used as the second electrode 26.

Further, in order to allow light emitted from the light-emitting layer included in each organic compound layer 23 to exit to the outside, any of the first electrode 21 and the second electrode 26 is adapted as a transparent or semi-transparent electrode. The transparency herein refers to having a transmittance of 80% or higher to visible light, and the semi-transparency refers to having a transmittance of 20% or higher and less than 80% to visible light.

### (5) Step of Forming Inorganic Sealing Film

While the organic light-emitting device according to the present invention is completed with the second electrode 26 formed, an inorganic sealing film is preferably stacked on the anode in order to suppress the infiltration of moisture, oxygen, etc., from the outside into the organic light-emitting device 20. The inorganic sealing film is preferably a SiN film, a lamination film of a SiN film and a SiO film, or the like, and preferably on the order of 0.5 to 4 ═m in film thickness. The SiN film can become thin films which have various properties by varying the deposition condition such as the substrate temperature or the deposition rate, but not to be considered to limit the present invention.

The manufacture of the organic light-emitting device in accordance with the manufacturing process described above can prevent defective light emissions due to flying organic compound fragments generated by cracking or peeling of the hole injection layer 22. As a result, it becomes possible to introduce the cleaning step for reducing foreign substances on the substrate. For this reason, it becomes possible to suppress the generation of defective light emissions such as dark spots generated subsequently, thereby leading to a quality improvement in thin-film sealing.

### Second Embodiment

### Method for Manufacturing Organic Light-Emitting Device B

Next, a method for manufacturing the organic light-emitting device B according to the present invention will be described. The organic light-emitting device B is specifically, a multi-color display. The method for manufacturing the organic light-emitting device according to the present invention includes at least the following steps (A) to (F) below.

### (A) Step of Forming Hole Injection Layer (Hole Injection Layer Formation Step)

### (B) Step of Forming Organic Compound Layer Including Light-Emitting Layer (Organic Compound Layer Formation Step)

(C) Step of forming Peeling Layer (Peeling Layer Formation Step)

### (D) Step of Processing Organic Compound Layer (Organic Compound Layer Processing Step)

### (E) Step of Removing Peeling Layer (Peeling Layer Removal Step)

In the present invention, the step (E) (peeling layer removal step) is a step of dissolving a peeling layer with the use of a polar solvent. In addition, in the present invention, the etching rate of (the constituent material of) the peeling layer against the polar solvent for use in the step (E) is at least higher than the etching rate of (the constituent material of) the organic compound layer. In this regard, when the peeling layer is composed of more than one layer, the etching rate of the constituent material of a predetermined layer included in the peeling layer against the polar solvent is higher than the etching rates of the constituent materials of the organic compound layer, and of other layer constituting the peeling layer. It is to be noted that the predetermined layer herein refers to a layer dissolved by the polar solvent in the step (E).

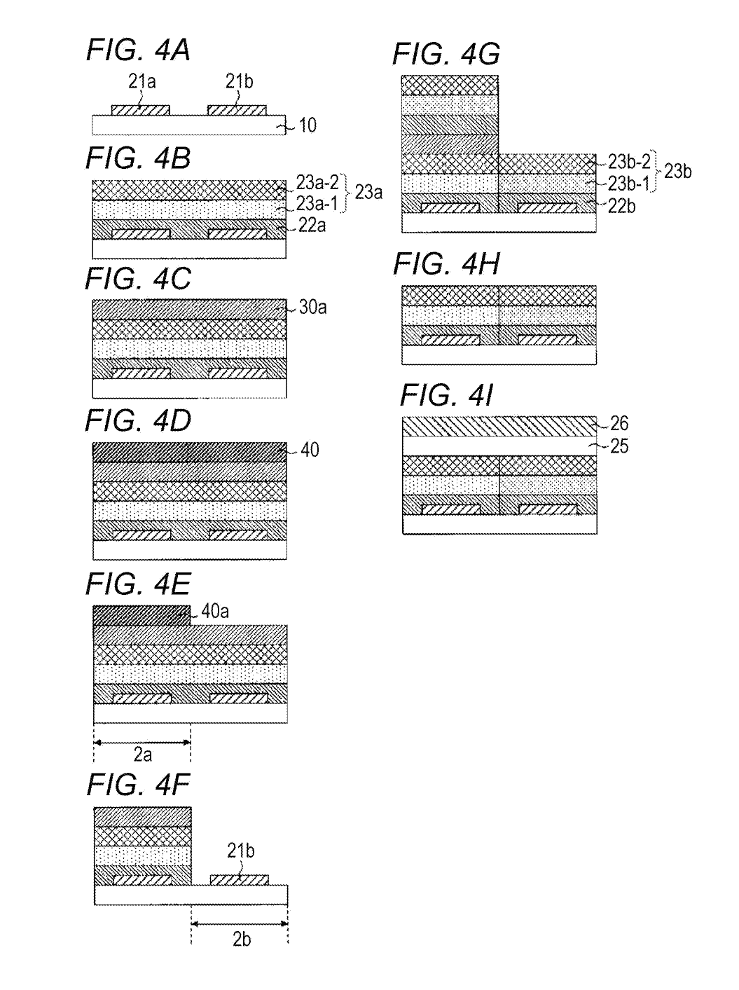

FIGS. 4A to 4I are schematic cross-sectional views illustrating a second embodiment in a method for manufacturing an organic light-emitting device according to the present invention. The organic light-emitting device according to the present embodiment includes two types of organic light-emitting devices. The method for manufacturing an organic light-emitting device according to the present invention includes, for example, the steps (1) to (19) described below.

However, in the present invention, the method for manufacturing an organic light-emitting device is not to be considered limited to the steps (1) to (19) below. While the second embodiment of the manufacturing method according to the present invention will be described below with reference to FIGS. 4A to 4I, sections in common with those in the first embodiment will be omitted. In addition, in the present embodiment, ends of hole injection layers 22, which need to be covered with a second organic compound layer 23b-2, will be described in detail after explaining the series of steps.

### (1) Step of Forming First Electrode (FIG. 4A)

First, first electrodes (21a, 21b) are formed on the substrate 10 in the same way as in the first embodiment (FIG. 4A).

The same materials as in the first embodiment can be also used for specific constituent materials of the first electrodes (21a, 21b).

### (2) Step of Forming Hole Injection Layer and First Organic Compound Layer (FIG. 4B)

A hole injection layer 22a and a first organic compound layer 23a-1, 23a-2 are sequentially formed on the substrate 10 with the first electrodes (21a, 21b) formed (FIG. 4B). It is to be noted that the first organic compound layers 23a-1 and 23a-2 herein may be simply referred to collectively as the first organic compound layer 23a in some cases. Hereinafter, the same applies to the second organic compound layer 23b.

The forming method and materials for the respective layers are adopted in the same manner as in the first embodiment. However, a material of which the etching rate against the polar solvent is less than or equal to the etching rate of a peeling layer 30a formed in a subsequent layer is selected for the material of a layer included in the first organic compound layer 23a-2.

### (3) Step of Forming Peeling Layer (FIG. 4C)

Next, the peeling layer 30a is formed on the first organic compound layer 23a-2 (FIG. 4C). The peeling layer 30a is a single layer in the present embodiment, but not to be considered limited thereto. More specifically, the peeling layer 30a may be a stacked body composed of multiple layers.

When the peeling layer 30a is a single layer as in the present embodiment, a material is selected as the constituent material of the peeling layer 30a so that the etching rate of the peeling layer 30a against the polar solvent for dissolving the peeling layer 30a is higher than the etching rate of the first organic compound layer 23a-2. This is because when the etching rate of the peeling layer 30a falls below the etching rate of a first organic compound layer 23a-2, there is a possibility that etching may progress down to a light-emitting layer included in the first organic compound layer 23a to decrease device characteristics.

Water-soluble inorganic materials such as LiF and NaCl, or water-soluble polymers such as polyvinyl alcohol (PVA) and polyvinylpyrrolidone (PVP) can be used as the constituent material of the peeling layer 30a. In addition, as long as the etching rate of the first organic compound layer 23a-2 against the polar solvent has an adequate selectivity, organic compounds having a polar substituent can be also used.

Known thin-film formation methods (vapor deposition methods, spin coat methods, coating methods, etc.) can be used as the method for forming the peeling layer 30a.

### (4) Step of Resist Layer (FIG. 4D)

Next, a resist layer 40 is formed on the peeling layer 30a (FIG. 4D). In this case, the resist layer 40 may be provided directly on the peeling layer 30a as illustrated in FIG. 4D. When the resist layer 40 is provided directly on the peeling layer 30a, the resist material is desirably selected so that the etching rate of the resist layer 40 against a developer solution is higher than that of the peeling layer 30a.

If the developer solution for the resist layer 40 is supposed to dissolve the constituent member (23a-1, 23a-2, 22a) of the organic light-emitting device, or dissolve or alter the peeling layer 30a, it is preferable to provide a protection layer (not illustrated) between the peeling layer 30a and the resist layer 40.

Inorganic materials such as a silicon nitride and a silicon oxide are preferred as the constituent material of the protection layer herein. The use of the protection layer can suppress the possibility of dissolving or altering the peeling layer 30a or the constituent members of the organic light-emitting device at the stage of forming or developing the resist layer 40. In addition, options can be increased for the material which can be used as the constituent material of the resist layer 40 formed on the peeling layer 30a.

### (5) Exposure and Development Step (FIG. 4E)

Next, patterning is carried out so that the region other than a region for providing the first sub pixel 2a is removed partially from the region with the resist layer 40 provided (FIG. 4E). The resist layer 40a left by this patterning is used as a mask layer in a subsequent step.

As the patterning method for the resist layer 40 in this case, a specific region (a region for providing the first sub pixel 2a or the other region) is selectively exposed first in consideration of the property of the resist layer 40. Next, a method is adopted for selectively removing, with the use of a developer solution, the resist layer 40 provided in the region other than the region for providing the first sub pixel 2a.

In this regard, when the resist layer 40 is subjected to patterning with the use of photolithography, there is a need to expose and develop the resist layer 40 as described above. However, without the use of photolithography, a method may be adopted in which the resist layer 40 is selectively formed as a mask layer in the region for providing the first sub pixel 2a with the use of a method such as an inkjet method or a printing method.

### (6) Step of Processing First Organic Compound Layer (FIG. 4F)

Subsequently, with the use of, as a mask layer, the resist layer 40a left in the region for providing the first sub pixel 2a, the peeling layer 30a, the first organic compound layer 23a, and the hole injection layer 22a are partially removed which are provided in the region covered with no resist layer 40. In this case, a dry etching method can be adopted as a method for removing the peeling layer 30a, the first organic compound layer 23a, and the hole injection layer 22a.

This step exposes a first electrode 21b included in the second sub pixel 2b (FIG. 4F). It is to be noted that the resist layer 40a used as a mask layer in this step may be partially removed, or entirely removed as illustrated in FIG. 4F. Even if the resist layer 40 is left in this step, a subsequent step ((8) Lift-Off Step) can remove the left resist layer 40a.

### (7) Step of Forming Hole Injection Layer, Second Organic Compound Layer (FIG. 4G)

Next, a hole injection layer 22b and a second organic compound layer 23b-1, 23b-2 are sequentially formed on the first electrode 21b included in the second sub pixel 2b (FIG. 4G). It is to be noted that in the sequential formation of the hole injection layer 22b and the second organic compound layer 23b, the hole injection layer 22b and the second organic compound layer 23b are formed in a region larger than the display region to encompass at least the display region.

The hole injection layer 22b formed in this step may be the same as or different from the hole injection layer 22a included in the first sub pixel 2a.

The second organic compound layer 23b formed in this step typically differs in emission color, film thickness of included layer, etc., as compared with the first organic compound layer 23a included in the first sub pixel 2a.

### (8) Lift-Off Step (FIG. 4H)

Next, the peeling layer 30a is dissolved in contact with a polar solvent in which the peeling layer 30a is soluble, for lift-off (peeling) of the positive injection layer 22b and second organic compound layer 23b formed on the peeling layer 30a above the first 21a (FIG. 4H).

In the present invention, the etching rate of the peeling layer 30a against the polar solvent is set to be higher than that of the first organic compound layer 23a-2. For this reason, the peeling layer 30a can be selectively dissolved and thereby removed.

### (9) Step of Forming Second Electrode, etc. (FIG. 4I)

Next, the sequential formation of the electron injection layer 25 and second electrode 26 on the organic compound layers (23a, 23b) completes the organic light-emitting device 2a in FIG. 3B (FIG. 4I). However, the electron injection layer 25 is a member provided if necessary, and it is not always necessary to provide the electron injection layer 25. In addition to the electron injection layer and the second electrode, a layer composed of a material which can be used commonly for the first sub pixel 2a and the second sub pixel 2b may be further formed, such as a charge transport layer.

The same material as in the first embodiment can be used as the constituent material of the second electrode 26.

While the organic light-emitting device according to the present invention is completed with the second electrode 26 formed, a known sealing member (not illustrated) is preferably provided in order to suppress the infiltration of moisture, oxygen, etc., from the outside into the organic light-emitting devices (20a, 20b).

Now, the ends of the hole injection layers 22 will be described which need to be covered with the second organic compound layers 23b-2.

The hole injection layer 22a and organic compound layer 23a included in the first sub pixel 2a are removed except for those in the region for providing the first sub pixel 2a in the step (6). Furthermore, at the stage of the hole injection layer 22a and organic compound layer 23a subjected to patterning, there is no need for the ends of the hole injection layer 22a to be covered with the organic compound layer 23a, because the ends are not brought into contact with the polar solvent.

In the subsequent step (7), the hole injection layer 22b and organic compound layer 23b included in the second sub pixel 2b are formed to cover at least the display region. Then, in the step (8), the hole injection layer 22b and organic compound layer 23b formed on the peeling layer 30a above the first electrode 21a are subjected to lift-off in contact with the polar solvent. More specifically, the ends of the hole injection layers 22a, where the infiltration of the polar solvent is likely to be caused, refer to the ends of the hole injection layer 22b before the patterning, which are formed outside the display region, and it is only necessary to cover the ends with the second organic compound layer 23b. When the second organic compound layer 23b is composed of more than one layer, it is only necessary to cover the ends of the hole injection layers 22a, which are formed outside the display region, with any layer included in the second organic compound layer 23b-2.

In the case of forming the organic compound layer 23a, 23b or the hole injection layer 22a, 22b by a vapor deposition method, methods for determining the deposition region for each layer include: determining the opening size of a mask; floating the mask with respect to the substrate to increase the component coming around; and adjusting the incident angle to the substrate for the deposition. However, the determination of the deposition region is not to be considered limited thereto. In the case of adopting the method of adjusting the incident angle to the substrate for the deposition, with the use of the same mask, the incident angle may be set to be small in the formation of the hole injection layer 22b, whereas the incident angle may be increased in the formation of the second organic compound layer 23b-2.

The manufacture of the organic light-emitting device in accordance with the manufacturing process described above is intended to, in the dissolution and thus removal of the peeling layer 30a, cover the ends of the hole injection layer (22b) with any layer (23b-2) included in the second organic compound layer (23b) which is lower in etching rate than the peeling layer 30a. For this reason, the hole injection layer (22b) can be kept from being cracked or peeled. Therefore, it is possible to prevent defective light emissions due to flying organic compound fragments generated by cracking or peeling of the hole injection layer (22a, 22b).

### Third Embodiment

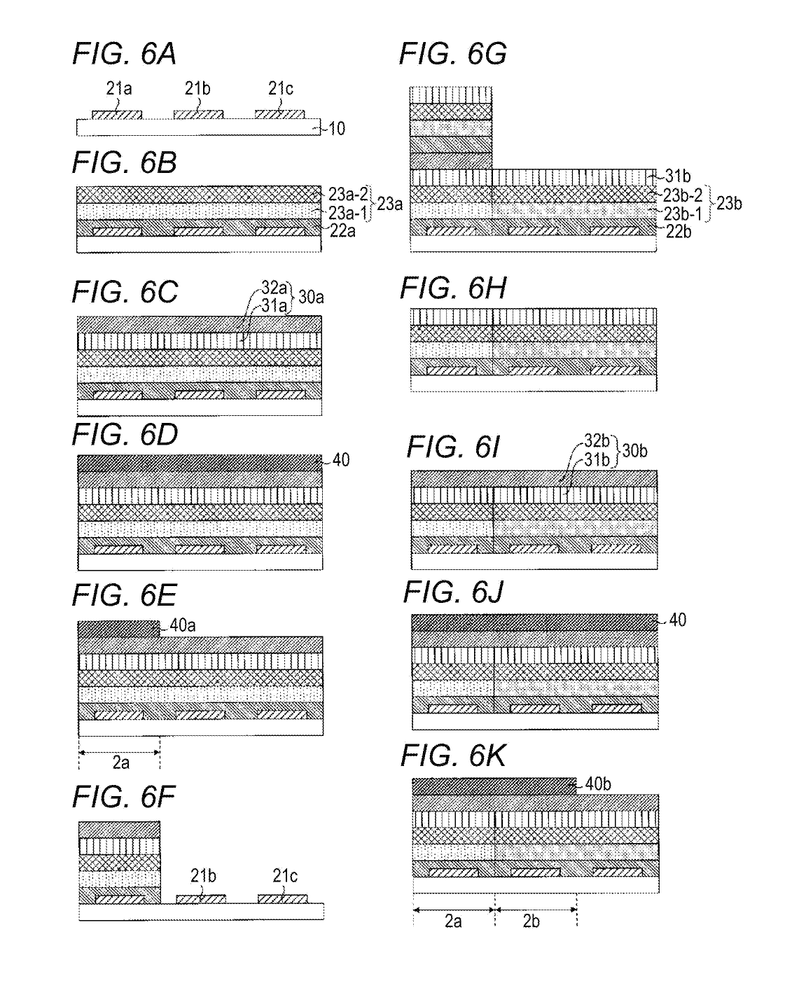

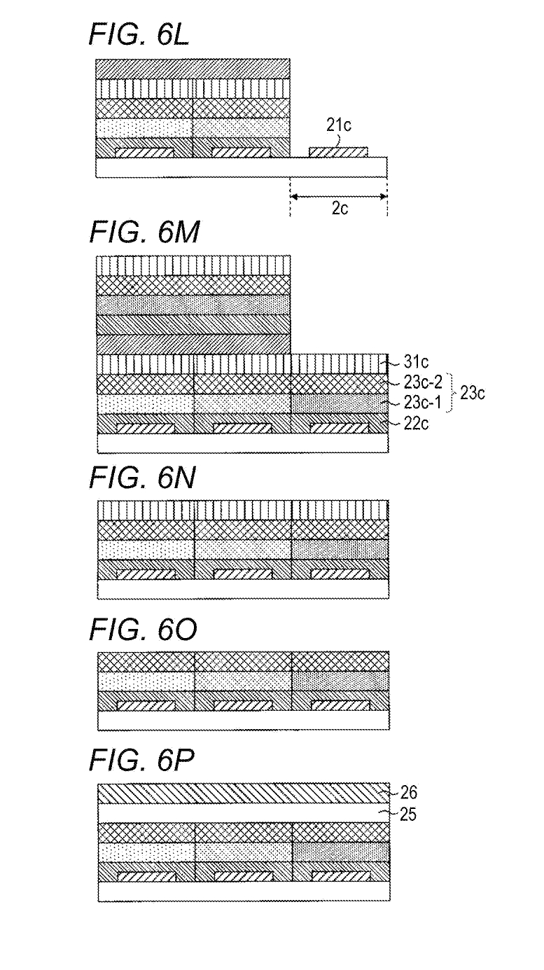

FIG. 6 is schematic cross-sectional views illustrating a third embodiment in a method for manufacturing an organic light-emitting device according to the present invention. The manufacturing process illustrated in FIGS. 6A to 6P can be conducted in the same way as the manufacturing process illustrated in FIGS. 4A to 4I, except that three types of organic light-emitting devices are formed, and that the peeling layer 30a is formed as a stacked body composed of more than one layer (first peeling layer 31a, second peeling layer 32a).

Examples of the constituent material of the first peeling layer 31a, for example, materials containing a polar site. Specifically, the examples include the following organic compounds containing heterocycles.

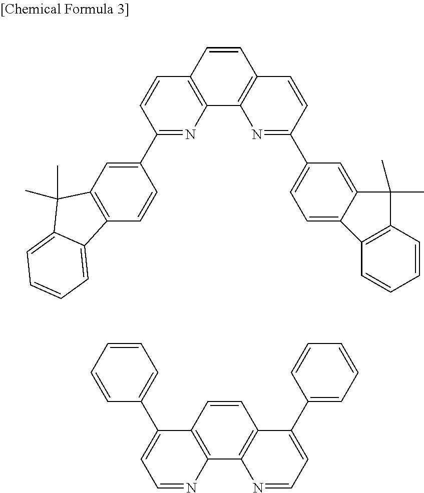

The group of compounds is dissolved in polar solvents (water, organic compounds having hetero atoms (N, O, S, etc.) (organic compounds having polar sites), mixed solvents composed of the compounds mixed, etc.). For this reason, for example, when an organic compound composed of only hydrocarbon that is not dissolved in the polar solvents is adopted as the constituent material of the organic compound layer 23a-2, whereas any from the group of compounds is adopted as the constituent material of the peeling layer 30a, the first peeling layer 31a will be selectively dissolved by the polar solvents.

A material that meets the following requirements is preferably selected as the constituent material of the second peeling layer 32a formed on the first peeling layer 31a.
Causing no damage to the first peeling layer 31a, the first organic compound layer 23a in the formation of the second peeling layer 32a;
Having a high etching rate against polar solvents which dissolve the first peeling layer 31a.

As the constituent material of the second peeling layer 32a, a material is preferably used of which the etching rate against the polar solvent for use in etching the first peeling layer 31a is 10 or more times as high as that of the first peeling layer 31a.

In addition, in the case of varying the polar solvents used for each of the first peeling layer 31a and the second peeling layer 32a from each other, for example, a material that has a low solubility in water is used as the constituent material of the first peeling layer 31a. Further, a material that is likely to be dissolved in water is used as the constituent material of the second peeling layer 32a.

In such a case, water-soluble inorganic materials such as LiF and NaCl, or water-soluble polymers such as polyvinyl alcohol (PVA) and polyvinylpyrrolidone (PVP) can be used as the constituent material of the second peeling layer 32a.

The studies carried out by inventors have found that when the peeling layer is composed of only a layer of water-soluble inorganic material or water-soluble polymer material as in Japanese Patent No. 4537207, it is difficult to remove the peeling layer without any residue even in the case of having a favorable condition for the etching rate against a dissolving solution that dissolves the peeling layer.

The water-soluble inorganic materials and water-soluble polymer materials shown herein as the constituent material of the second peeling layer 32a are insulating materials, and thus, when residues of these materials are left on the outermost surfaces of the organic compound layers, device characteristics may be decreased in some cases.

In particular, when the peeling layer is composed of a polymer material of a polymer such as polyvinyl alcohol or polyvinylpyrrolidone, or alcohol-soluble nylon, this issue is likely to be caused. Moreover, it has been determined that this situation is also caused between the organic material constituting the peeling layer and the organic compound layer provided under the peeling layer in the present invention.

For example, in the case of using, for the peeling layer, a material that is likely to leave a peeling layer material residue, such as a water-soluble polymer, before the formation of the second peeling layer 32a composed of a water-soluble polymer on the organic compound layer 23a-2, the formation of the first peeling layer 31a composed of other material makes it easy to remove the residue.

In this case, a material that causes no decrease in device characteristics even when a residue of the material is left on the surface of the organic compound layer 23a-2 is preferably selected as the constituent material of the first peeling layer 31a. Specifically, the selection of a carrier transport material is particularly preferred without decreasing the device characteristics, because carrier transfers will not be hindered even when the material is present on the surface of the organic compound layer. The above-mentioned compounds having polar sites herein as the constituent material of the first peeling layer 31a are compounds that will not hinder carrier transfers even when the compounds are present on the surface of the organic compound layer.

The present invention will be described below in detail with reference to examples.

### EXAMPLES

### Example 1

In accordance with the manufacturing process illustrated in FIGS. 3A to 3E, the organic light-emitting device A in FIG. 1C was prepared. It is to be noted that while the light-emitting layer is a blue light-emitting layer, the present invention is not limited to this layer.

(1) Step of Forming Substrate with Electrode (FIG. 3A)

First, AlNd was deposited by a sputtering method over the entire surface of the substrate 10 to form a reflection electrode. In this case, the AlNd film was 100 nm in film thickness. Next, an ITO was deposited by a sputtering method onto the reflection electrode to form an ITO film. In this case, the ITO film was 10 nm in film thickness.

Next, the lamination film composed of the reflection electrode (AlNd film) and the ITO film was subjected to patterning by the use of a known photolithography method. This patterning formed more than one first electrode (21) each included in the sub pixel 2 (FIG. 3A). Next, as a pixel separation film 9, a silicon nitride film was formed by CVD, a photoresist further formed thereon was subjected to patterning by photolithography, and desired openings were provided as illustrated in FIG. 1B by dry etching through the use of a CF4 gas with the patterned resist as a mask. The resist residue left on the pixel separation film was removed by dry etching with an oxygen gas. Next, the substrate 10 with the first electrodes (21) provided was subjected to a UV ozone treatment.

It is to be noted that a substrate with a circuit, including a base material (not illustrated), a circuit (not illustrated) provided on the base material for driving each organic light-emitting device (20), and an insulating layer (not illustrated) for coating the circuit, was used for the substrate 10 for use in this example. In addition, although not illustrated in FIG. 1C or 3A, each first electrode (21) is electrically connected to the circuit through a contact hole provided in a predetermined region of the insulating layer.

### (2) Step of Forming Hole Injection Layer

Next, the following compound 1 was deposited on the substrate 10 and the first electrodes (21) to form the hole injection layer 22, by a vacuum deposition method with the use of a vapor deposition mask including openings for a region (display region) corresponding to the deposition region 3 illustrated in FIG. 1A. In this case, the hole injection layer 22 was 50 nm in film thickness.

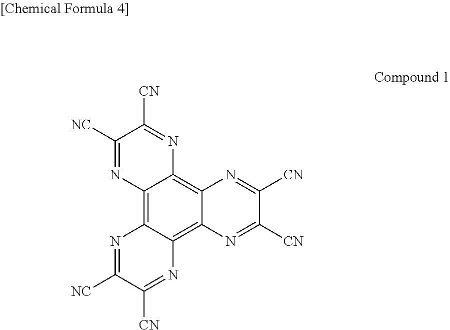 [SMILES: N#Cc1nc2c3nc(C#N)c(C#N)nc3c3nc(C#N)c(C#N)nc3c2nc1C#N]

### (3) Step of Forming First Organic Compound Layer

Next, an organic compound layer 23-1 including a light-emitting layer (blue light-emitting layer) for emitting blue light was formed on the hole injection layer 22 by continuous deposition through the use of a vacuum deposition method.

First, the same vapor deposition mask as the vapor deposition mask used in the formation of the hole injection layer 22 was used to form a hole transport layer with a film thickness of 70 nm. Next, the light-emitting layer including a blue light-emitting material was formed to have a film thickness of 30 nm.

Next, with the use of a vapor deposition mask including openings for a region corresponding to the deposition region 4 of the substrate 10, specifically as illustrated in FIG. 1A, the following compound 2 was deposited as a hole blocking layer to have a film thickness 10 nm in the deposition region 4 illustrated in FIG. 1A, thereby providing the organic compound layer 23-2. Next, with the use of the same vapor deposition mask, an organic compound to serve as an electron transport material was deposited to have a film thickness of 20 nm as a charge transport layer (electron transport layer) (not illustrated).

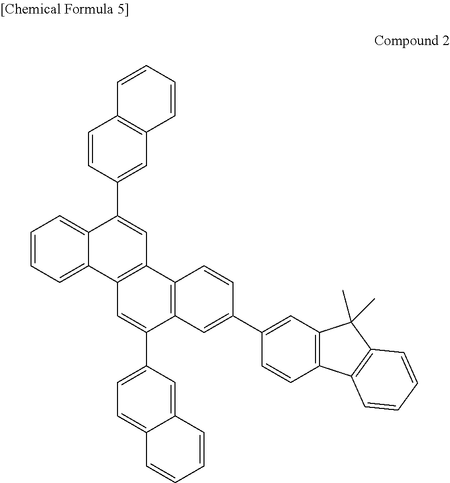 [SMILES: CC1(C)c2ccccc2-c2ccc(-c3ccc4c(c3)c(-c3ccc5ccccc5c3)cc3c5ccccc5c(-c5ccc6ccccc6c5)cc43)cc21]

### (5) Cleaning Step (Not Illustrated)

Next, the surface of the substrate 10 was cleaned with pure water. For the cleaning, a two-fluid nozzle composed of a nitrogen gas (30 L/min) and pure water (1 L/min) was used. In the step with the use of water, such as this step, the ends of the hole injection layer 22 were coated with the organic compound layer 23-2, because the organic compound layer 23-2 was formed over a larger area than the hole injection layer 22. For this reason, no damage to the hole injection layer 22 was found after carrying out this step.

### (6) Step of Forming Electron Injection Layer (FIG. 3D)

Next, an organic compound to serve as a charge transport material and cesium carbonate (Cs₂CO₃) were co-deposited on the charge transport layer to form an electron injection layer. In this case, the electron injection layer was 20 nm in film thickness.

### (7) Step of Forming Second Electrode (FIG. 3D)

Next, Ag was deposited on the electron injection layer 25 by a sputtering to form a semi-transparent second electrode 26 with a film thickness of 16 nm (FIG. 3D).

### (8) Sealing Step (FIG. 3E)

Next, a silicon nitride film (SiNx) was formed as an inorganic sealing film 50 to have a film thickness of 2 □m on the second electrode 26 with the use of CVD, thereby providing the organic light-emitting device A with the cross-sectional shape in FIG. 1B.

### Example 2

Based on the manufacturing process illustrated in FIGS. 6A to 6P, the organic light-emitting device B-b illustrated in FIG. 2C was prepared.

(1) Step of Forming Substrate with Electrode (FIG. 6A)

First, AlNd was deposited by a sputtering method over the entire surface of the substrate 10 to form a reflection electrode. In this case, the AlNd film was 100 nm in film thickness. Next, an ITO was deposited by a sputtering method onto the reflection electrode to form an ITO film. In this case, the ITO film was 10 nm in film thickness.

Next, the lamination film composed of the reflection electrode (AlNd film) and the ITO film was subjected to patterning by the use of a known photolithography method. This patterning formed more than one first electrode (21a, 21b, 21c) each included in the first sub pixel 2a, the second sub pixel 2b, or the third sub pixel 20c (FIG. 6A). Next, the substrate 10 with the first electrodes (21a, 21b, 21c) provided was subjected to a UV ozone treatment.

It is to be noted that a substrate with a circuit, including a base material (not illustrated), a circuit (not illustrated) provided on the base material for driving each organic light-emitting device (20a, 20b, 20c), and an insulating layer (not illustrated) for coating the circuit, was used for the substrate 10 for use in this example. In addition, although not illustrated in FIG. 2C, 7A or 7B, each first electrode (21a, 21b, 21c) is electrically connected to the circuit through a contact hole provided in a predetermined region of the insulating layer.

### (2) Step of Forming Hole Injection Layer

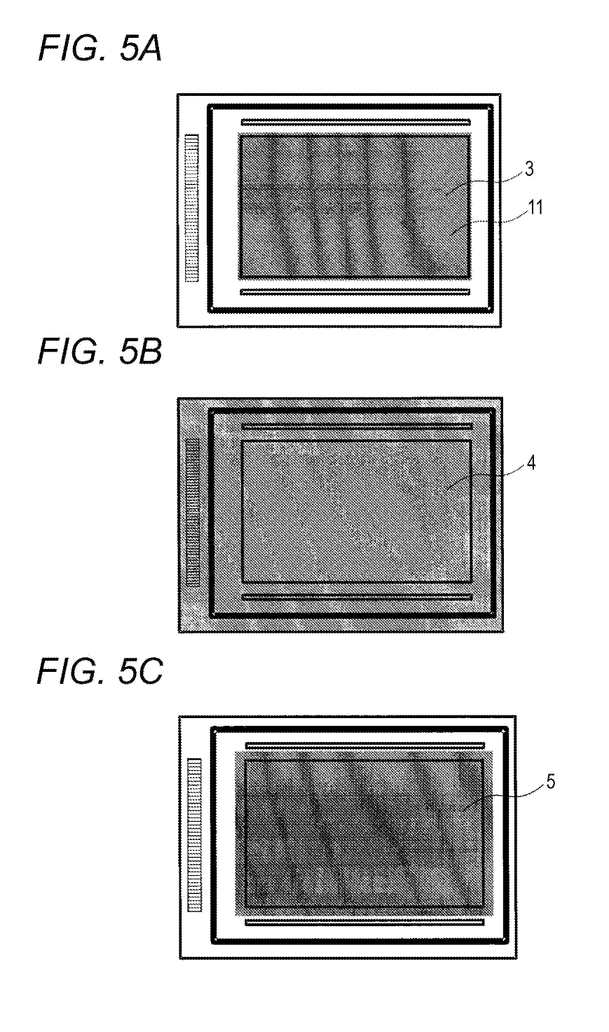

Next, the following compound 1 was deposited on the substrate 10 and the first electrodes (21a, 21b, 21c) to form the hole injection layer 22a, by a vacuum deposition method with the use of a mask including openings for the deposition region 3 illustrated in FIG. 5A. In this case, the hole injection layer 22a was 50 nm in film thickness.

### (3) Step of Forming First Organic Compound Layer

Next, a first organic compound layer 23a including a first light-emitting layer (blue light-emitting layer) for emitting blue light was formed on the hole injection layer 22a by continuous deposition through the use of a vacuum deposition method. It is to be noted that the first organic compound layers 23a-1 and 23a-2 herein may be simply referred to collectively as the first organic compound layer 23a in some cases. Hereinafter, the same applies to the second organic compound layer 23b and the third organic compound layer 23c.

First, the same vapor deposition mask as the vapor deposition mask used in the formation of the hole injection layer 22a was used to form the first organic compound layer 23a-1 including a hole transport layer (not illustrated) with a film thickness of 70 nm and a first light-emitting layer containing a blue light-emitting material with a film thickness of 30 nm. Next, with the use of a vapor deposition mask including openings for a region corresponding to the deposition region 4 illustrated in FIG. 5B, the following compound 2 was deposited to form a first organic compound layer 23a-2 as a hole blocking layer in the deposition region 4 illustrated in FIG. 6 (FIG. 6B). In this case, the hole blocking layer 23a-2 was 10 nm in film thickness.

### (5) Step of Forming Peeling Layer (FIG. 6C)

Next, the peeling layer 30 composed of the first peeling layer 31a and second peeling layer 32a sequentially stacked was formed by the following method. First, the following compound 3 was deposited on the hole blocking layer 23a-2 to form the first peeling layer 31a, by a vapor deposition method with the use of the vapor deposition mask used in the formation of the hole blocking layer 23a-2. In this case, the first peeling layer 31a was 40 nm in film thickness.

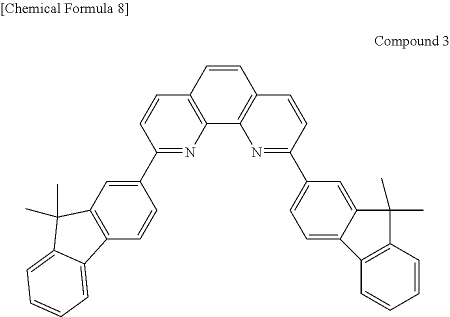

Next, polyvinylpyrrolidone (PVP) as a water-soluble polymer material and water were mixed to prepare a PVP aqueous solution. Next, the prepared PVP aqueous solution was applied and deposited on the first peeling layer 31a by a spin coat method. In this case, the formation of the first peeling layer 31a over the entire surface of the substrate 10 can make wettability for the spin coating uniform on the substrate, with film-forming properties improved. Next, the formed PVP film was dried to form the second peeling layer 32a of 500 nm in film thickness. Thus, the peeling layer 30a was formed which was composed of the stacked first peeling layer 31a and second peeling layer 32a (FIG. 6C).

### (6) Step of Forming Resist Layer (FIG. 6D)

Next, a commercially available photoresist material (from AZ Electronic Materials, Product Name “AZ1500”) was deposited on the second peeling layer 32a by a spin coat method, and the solvent contained in the photoresist material was then evaporated to form the resist layer 40 (FIG. 6D). In this case, the resist layer 40 was 1000 nm in film thickness.

### (7) Exposure and Development Step (FIG. 6E)

Next, the substrate 10 with the layers formed up to the resist layer 40 was set in an exposure apparatus, and exposed for 40 seconds through a photomask, so as to leave the resist layer 40a formed in the region for providing the first sub pixel 2a. After the exposure, a developer solution (from AZ Electronic Materials, Product Name “312MIF” diluted with water to have a concentration of 50%) for the resist layer 40 was used to carry out development for 1 minute. This development treatment removed the resist layer 40 formed in the region other than the region for providing the first sub pixel 2a (FIG. 6E).

### (8) Step of Processing First Organic Compound Layer, etc. (FIG. 6F)

Next, with the resist layer 40a left after carrying out the previous step (exposure and development step) as a mask, the peeling layer 31 coated with no resist layer 40a was removed by dry etching. In this case, the etching gas (reaction gas) was oxygen, the flow rate of the etching gas was 20 sccm, the pressure in the apparatus was 8 Pa, the output was 150 W, and the treatment time was 5 minutes.

Next, with the processed peeling layer 31 as a mask, the first organic compound layer 23a and hole injection layer 22a coated with no peeling layer 31 were sequentially processed by dry etching. This processing exposed the first electrode 21b provided in the second sub pixel 2b and the first electrode 21c provided in the third sub pixel 2c. In this case, the conditions for processing the first organic compound layer 23a and the hole injection layer 22a were made in the same way as the conditions for processing the peeling layer 31. In addition, on completion of the processing (partial etching) of the hole injection layer 22a, the resist layer 40 provided on the peeling layer 31 was removed by the etching (FIG. 6F).

### (9) Step of Processing Second Organic Compound Layer, etc.

Next, after the exposed first electrodes (21b, 21c) were subjected to a UV ozone treatment, the compound 1 was deposited on the substrate 10 and the first electrodes (21b, 21c) to form the hole injection layer 22b, by a vacuum deposition method with the use of a mask including openings for the deposition region 3 illustrated in FIG. 5A. In this case, the hole injection layer 22b was 50 nm in film thickness.

Next, the second organic compound layer 23b including a light-emitting layer (green light-emitting layer) for emitting green light was formed on the hole injection layer 22b by a method similar to that in the step (3). First, the same vapor deposition mask as the vapor deposition mask used in the formation of the hole injection layer 22b was used to form the second organic compound layer 23b-1 including a hole transport layer (not illustrated) with a film thickness of 110 nm and the light-emitting layer 23b-1 containing a known green light-emitting material with a film thickness of 30 nm. Next, the compound 2 was deposited to form a hole blocking layer 23b-2 over the entire surface of the substrate 10, specifically, in the region corresponding to the deposition region 4 illustrated in FIG. 5B. In this case, the second organic compound layer 23b-2 as a hole blocking layer was 10 nm in film thickness.

### (10) Step of Forming First Peeling Layer (FIG. 6G)

Next, the compound 3 was deposited on the second organic compound layer 23b-2 to form the first peeling layer 31b, by a vacuum deposition method with the use of the vapor deposition mask used in the formation of the second organic compound layer 23b-2 (FIG. 6G). In this case, the first peeling layer 31b was 40 nm in film thickness.

### (11) Lift-Off Step (FIG. 6H)

Next, the substrate 10 with the layers formed up to the first peeling layer 31b was immersed in water (running water) as a peeling liquid for the second peeling layer 32a. In this case, the etching rate of the second peeling layer 32a composed of water-soluble polyvinylpyrrolidon against water is 100 or more times as high as the etching rate of the hole blocking layer (23a-2, 23b-2) or first peeling layer (31a, 31b) against water. For this reason, the second peeling layer 32a was able to be selectively dissolved and removed. In addition, the dissolution and removal of the second peeling layer 32a succeeded in lift-off of the layers (hole injection layer 22b, second organic compound layer 23b, first peeling layer 31b) formed on the second peeling layer 32a (FIG. 6H). Thus, the first organic compound layer 23a was able to be processed into a desired pattern shape.

### (12) Step of Forming Second Peeling Layer (FIG. 6I)

Next, polyvinylpyrrolidone (PVP) as a water-soluble polymer material and water were mixed to prepare a PVP aqueous solution. Next, the prepared PVP aqueous solution was applied and deposited on the first peeling layer 31b by a spin coat method. Next, the formed PVP film was dried to form the second peeling layer 32b of 500 nm in film thickness (FIG. 6I).

### (13) Step of Forming Resist Layer (FIG. 6J)

Next, a commercially available photoresist material (from AZ Electronic Materials, Product Name “AZ1500”) was deposited on the peeling layer 31 by a spin coat method, and the solvent contained in the photoresist material was then evaporated to form the resist layer 40 (FIG. 6J). In this case, the resist layer 40 was 1000 nm in film thickness.

### (14) Exposure and Development Step (FIG. 6K)

Next, the substrate 10 with the layers formed up to the resist layer 40 was set in an exposure apparatus, and exposed for 40 seconds through a photomask, so as to leave the resist layer 40b formed in the region for providing the first sub pixel 2a and the second sub pixel 2b. After the exposure, a developer solution (from AZ Electronic Materials, Product Name “312MIF” diluted with water to have a concentration of 50%) for the resist layer 40 was used to carry out development for 1 minute. This development treatment removed the resist layer 40 formed in the region other than the region for providing the first sub pixel 2a and the second sub pixel 2b (FIG. 6K).

### (15) Step of Processing Second Organic Compound Layer, etc. (FIG. 6L)

Next, with the resist layer 40b left after carrying out the previous step (exposure and development step) as a mask, the peeling layer 31 coated with no resist layer 40b was removed by dry etching. In this case, the etching gas (reaction gas) was oxygen, the flow rate of the etching gas was 20 sccm, the pressure in the apparatus was 8 Pa, the output was 150 W, and the treatment time was 5 minutes.

Next, with the processed peeling layer 31 as a mask, the second organic compound layer 23b and hole injection layer 22b coated with no peeling layer 31 were sequentially processed by dry etching. This processing exposed the first electrode 21c provided in the third sub pixel 2c. In this case, the conditions for processing the second organic compound layer 23b and the hole injection layer 22b were made in the same way as the conditions for processing the peeling layer 31. In addition, on completion of the processing (partial etching) of the hole injection layer 22a, the resist layer 40b provided on the peeling layer 31 was removed by the etching (FIG. 6L).

### (16) Step of Forming Third Organic Compound Layer, etc.

Next, after the exposed first electrode 21c was subjected to a UV ozone treatment, the compound 1 was deposited on the substrate 10 and the first electrode 21c) to form the hole injection layer 22c, by a vacuum deposition method with the use of a mask including openings for the deposition region 3 illustrated in FIG. 5A. In this case, the hole injection layer 22c was 50 nm in film thickness.

Next, the third organic compound layer 23c including a light-emitting layer (red light-emitting layer) for emitting red light was formed on the hole injection layer 22c by a method similar to that in the step (3). First, the same vapor deposition mask as the vapor deposition mask used in the formation of the hole injection layer 22c was used to form the third organic compound layer 23c-1 including a hole transport layer (not illustrated) with a film thickness of 150 nm and the light-emitting layer 23c-1 containing a known red light-emitting material with a film thickness of 30 nm. Next, with the use of a vapor deposition mask including openings for a region corresponding to a deposition region 5 of the substrate 10, specifically illustrated in FIG. 5C, the compound 2 was deposited in the deposition region 5 illustrated in FIG. 5C to form a third organic compound layer 23c-2 as a hole blocking layer. In this case, the third organic compound layer 23c-2 as a hole blocking layer was 10 nm in film thickness.

### (17) Step of Forming First Peeling Layer (FIG. 6M)

Next, the compound 3 was deposited on the third organic compound layer 23c-2 to form the first peeling layer 31c, by a vacuum deposition method with the use of the vapor deposition mask used in the formation of the organic compound layer 23c-2 (FIG. 6M). In this case, the first peeling layer 31c was 40 nm in film thickness.

### (18) Lift-Off Step (FIG. 6N)

Next, the substrate 10 with the layers formed up to the first peeling layer 31c was immersed in water (running water) as a peeling liquid for the second peeling layer 32b. The dissolution of the second peeling layer 32b achieved lift-off of the layers formed on the second peeling layer 32b (FIG. 6N). The steps mentioned above achieved patterning of the three types of organic compound layers (23a, 23b, 23c) into predetermined shapes.

### (19) Step of Removing First Peeling Layer (FIG. 60)

Next, the substrate 10 was immersed in a mixed solution of IPA and water (a solution composed of polar solvents) to remove the first peeling layers (31a, 31b, 31c) provided on the respective organic compound layers (23a, 23b, 23c). As the solvent for use in this step herein, a mixed solution was used which was obtained by mixing and adjusting water and isopropyl alcohol (IPA) so that the IPA concentration was 60 weight %, and the immersion time was 20 seconds. In addition, in the use of polar solvents, such as this step, the ends of the hole injection layer 22c were coated with the hole blocking layer (23c-2), because the hole blocking layer 23c-2 was formed over a larger area than the hole injection layer 22c. For this reason, no damage to any hole injection layer (22c) was found after carrying out this step.

### (20) Step of Forming Electron Injection Layer

Next, an organic compound to serve as a charge transport material was deposited on the respective organic compound layers (23a, 23b, 23c) to form a charge transport layer (electron transport layer: not illustrated). In this case, the charge transport layer was 20 nm in film thickness. Next, an organic compound to serve as a charge transport material and cesium carbonate (Cs₂CO₃) were co-deposited on the charge transport layer to form an electron injection layer 25. In this case, the electron injection layer was 20 nm in film thickness.

### (21) Step of Forming Second Electrode (FIG. 6N)

Next, Ag was deposited on the electron injection layer 25 by a sputtering to form a semi-transparent second electrode 26 with a film thickness of 16 nm (FIG. 6N).

### (22) Sealing Step

Next, an adhesive composed of a UV curable resin was used to bond a sealing glass 60 to the substrate 10 under a nitrogen atmosphere, for sealing of the organic light-emitting devices (20a, 20b, 20c). Thus, the organic light-emitting device B-b was obtained as illustrated in FIG. 2C and (b).

### Comparative Example 1

In the formation of the organic compound layer (23a-2, 23b-2, 23c-2) as a hole blocking layer in Example 2, the vapor deposition mask used in the formation of the hole injection layer (22a, 22b, 22c) was used to form the organic compound layer. Except for this difference, the organic light-emitting device B-b was prepared by a method similar to that in Example 2.

### [Evaluation of Organic Light-Emitting Device]

For the obtained organic light-emitting devices, when the surfaces of the organic light-emitting devices formed in the devices were observed with a microscope, the ends of the hole injection layers (22, 22c) were not cracked or peeled in the case of the organic light-emitting devices according to Examples 1 to 2. For this reason, there was not any non-emission point generated due to flying fragments generated by peeling of the hole injection layers (22, 22c).

On the other hand, in the case of the organic light-emitting device according to Comparative Example 1, the ends of the hole injection layer 22c were cracked or peeled.

In addition, for the obtained organic light-emitting devices, when the organic light-emitting devices constituting the organic light-emitting devices were activated for all of the colors to emit white light, there were flying fragments generated by peeling of the hole injection layers, at about 80% of non-emission points in Comparative Example 1.

From the results described above, it has been demonstrated that the organic light-emitting device according to the present invention is an organic light-emitting device which is capable of efficiently emitting light. More specifically, cracking or peeling can be reduced at the ends of the hole injection layer by covering with any layer included in the organic compound layer composed of a material that is less likely to be dissolved in polar solvents so as to cover the hole injection layer with an electron-withdrawing property. Further, it can be confirmed that flying fragments from the organic compound layer can be reduced to stably prepare an organic light-emitting device for favorable light emissions.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-004003, filed Jan. 11, 2013, which is hereby incorporated by reference herein in its entirety.

What is claimed is:

1. An organic light-emitting device comprising a display region having an organic light-emitting device placed on a substrate, wherein the organic light-emitting device comprises:
a first electrode provided on the substrate;
a hole injection layer provided on the first electrode;
an organic compound layer provided on the hole injection layer, the organic compound layer including a light-emitting layer; and
a second electrode provided on the organic compound layer,
wherein the hole injection layer is a layer including an organic compound having an electron-withdrawing substituent, and a layer included in the organic compound layer coats an end of the hole injection layer, the end provided outside the display region.

2. The organic light-emitting device according to claim 1, further comprising a sealing film comprising an inorganic material, the sealing film covering the second electrode.

3. The organic light-emitting device according to claim 1, wherein the layer included in the organic compound layer, configured to coat the end of the hole injection layer, the end provided outside the display region, is a hole blocking layer.

4. The organic light-emitting device according to claim 1, wherein one type of organic light-emitting device is one-dimensionally placed in the display region.

5. The organic light-emitting device according to claim 1, wherein multiple types of organic light-emitting devices configured to emit different colors from each other are two-dimensionally placed in the display region.

6. A method for manufacturing the organic light-emitting device according to claim 1, the method comprising the steps of:
forming a hole injection layer on a first electrode on a substrate;
forming an organic compound layer including a light-emitting layer; and
bringing the organic compound layer into contact with a polar solvent,
wherein the hole injection layer is a layer including an organic compound having an electron-withdrawing substituent, and
the layer included in the organic compound layer is formed to coat an end of the hole injection layer, the end provided outside the display region, in the step of forming the organic compound layer.

7. The method for manufacturing the organic light-emitting device according to claim 6, the method comprising the steps of: forming a peeling layer on the organic compound layer; subjecting the organic compound layer to patterning; and removing the peeling layer.

8. The manufacturing method according to claim 6, wherein the polar solvent is water or an aqueous solution obtained by mixing water and other polar solvent.

9. The manufacturing method according to claim 6, wherein the step of coming into contact with the polar solvent is a cleaning step, a lift-off step, or an etching step.

10. The method for manufacturing the organic light-emitting device according to claim 6,
wherein the step of removing the peeling layer is a step of etching the peeling layer with a polar solvent, and an etching rate of a constituent material of the peeling layer against the polar solvent is higher than an etching rate of a constituent material of the organic compound layer.

11. The method for manufacturing the organic light-emitting device according to claim 6,
wherein the step of removing the peeling layer is a step of dissolving the peeling layer with a polar solvent, and
an etching rate of a constituent material of a predetermined layer of the peeling layer against the polar solvent is higher than etching rates of constituent material of the organic compound layer, and of other layer constituting the peeling layer.
